(19) United States
(12) Patent Application Publication
(10) Pub. No.: US 2025/0329543 A1
(43) Pub. Date: Oct. 23, 2025

(54) METHOD INCLUDING UNDER-ETCHING AN ION-INDUCED DAMAGE LAYER TO FACILITATE SEPARATION OF A SUBSTRATE FILM LAYER FROM AN UNDERLYING SUBSTRATE BULK REGION

(71) Applicant: Microchip Technology Incorporated, Chandler, AZ (US)

(72) Inventor: Sergey Maximenko, Colorado Springs, CO (US)

(73) Assignee: Microchip Technology Incorporated, Chandler, AZ (US)

(21) Appl. No.: 18/755,022

(22) Filed: Jun. 26, 2024

Related U.S. Application Data
(60) Provisional application No. 63/637,414, filed on Apr. 23, 2024.

(51) Int. Cl. H01L 21/311; H01L 21/3115; H01L 21/677; H01L 21/822; H01L 21/8252; H01L 21/8254

(52) U.S. Cl. CPC H01L 21/31111; H01L 21/31116; H01L 21/31155; H01L 21/67739; H10D 84/038; H10D 84/05; H10D 84/07

(57) ABSTRACT

A method includes performing an ion beam implant in a semiconductor substrate to form an ion-induced damage layer having a damaged structure, wherein a portion of the substrate above the ion-induced damage layer defines a substrate film region, and a portion below the ion-induced damage layer defines a bulk substrate region. Semiconductor device components are formed on the substrate film region, wherein the substrate film region and semiconductor device components formed thereon define a substrate film-based semiconductor device structure. Vertical openings are formed through the substrate film-based semiconductor device structure and extending down to the ion-induced damage layer. An under-etch is performed through the openings to partially remove the ion-induced damage layer. The substrate film-based semiconductor device structure is separated from the bulk substrate region at the partially removed ion-induced damage layer, and the separated substrate film-based semiconductor device structure is mounted on a carrier.

### RELATED APPLICATION

This application claims priority to commonly owned U.S. Provisional Patent Application No. 63/637,414 filed Apr. 23, 2024, the entire contents of which are hereby incorporated by reference for all purposes.

### TECHNICAL FIELD

The present disclosure relates to a method including under-etching an ion-induced damage layer to facilitate separation of a substrate film layer from an underlying substrate bulk region.

### BACKGROUND

In conventional manufacturing of semiconductor devices formed on certain substrates, for example silicon carbide (SiC), gallium nitride (GaN), diamond, or other expensive substrates, semiconductor devices (e.g., transistors) are formed on a thin substrate film (e.g., a thin SiC, GaN, or diamond film), to control costs. However, producing devices on a thin substrate film often results in waferbowing and/or wrapping of the structure, which may hinder the fabrication of device structures with consistent electrical characteristics across a wafer.

There is a need for improved production of semiconductor devices on a thin substrate, for example a thin SiC, GaN, or diamond substrate.

### SUMMARY

The present disclosure provides methods for forming semiconductor device structures on a semiconductor substrate (e.g., a silicon carbide (SiC), gallium nitride (GaN), or diamond substrate) before reducing a thickness of the substrate, e.g., by detaching (separating) a thin layer of the substrate from a thicker bulk region of the substrate. In some examples, an ion beam implantation is performed in the substrate to form a ion-induced damage layer a partial depth in the substrate to define (a) an substrate film region above the damage layer and (b) a bulk substrate region below the damage layer. Semiconductor device components may be formed on the substrate film region, e.g., including growing an epitaxial region over the substrate film region and forming metal structures over the epitaxial region.

Vertical openings may be formed through the structure and extending down to the ion-induced damage layer, e.g., using a plasma etch or a mechanical cutting process. An under-etch may be performed through the vertical openings to partially remove the ion-induced damage layer, thereby further weakening the ion-induced damage layer. The substrate film region having the semiconductor device components formed thereon may be separated from the bulk substrate region at the partially removed and weakened ion-induced damage layer. The separated structure (including the substrate film region and semiconductor device components formed thereon) may be mounted on a carrier, which may be further diced to define a plurality of discrete devices.

Thus, some examples provide a process to detach a thin semiconductor layer (e.g., a thin layer of SiC, GaN, or diamond) having processed semiconductor structures formed thereon, from the thicker wafer substrate (e.g., SiC, GaN, or diamond wafer substrate). This detached layer may then be attached to a high electrical/thermal conductivity dice carrier, and diced to form a plurality of discrete devices.

In some examples, the separated bulk substrate region of the semiconductor substrate (e.g., SiC, GaN, or diamond wafer substrate) may be reused multiple times to produce a new series of devices, wherein a respective thin layer of the substrate is removed during each iteration.

The disclosed methods may be used to create device structures from SiC, GaN, or diamond or other semiconductor materials, for example for highly conductive electrical/thermal and cost-efficient substrates. The disclosed methods may be used, for example, for high-power switching structures composed of SiC or GaN or diamond.

In some examples, the disclosed methods may reduce the cost of single crystal SiC substrates and improve electrical device performance of resulting devices.

One aspect provides a method including performing an ion beam implant in a semiconductor substrate to form an ion-induced damage layer at an implant depth in the semiconductor substrate, wherein a portion of the substrate above the ion-induced damage layer defines a substrate film region, and a portion of the substrate below the ion-induced damage layer defines a bulk substrate region, and the ion-induced damage layer has a damaged structure relative to the substrate film region and the bulk substrate region. Semiconductor device components are formed on the substrate film region, wherein the substrate film region and the semiconductor device components formed thereon define a substrate film-based semiconductor device structure. A plurality of vertical openings are formed through the substrate film-based semiconductor device structure and extending to the ion-induced damage layer. An under-etch is performed through the vertical openings to partially remove the ion-induced damage layer. The substrate film-based semiconductor device structure is separated from the bulk substrate region, wherein the separation occurs at the partially removed ion-induced damage layer, and the separated substrate film-based semiconductor device structure is mounted on a carrier.

In some examples, the method includes securing a transfer device to the top side of the semiconductor device structure prior to separating the substrate film-based semiconductor device structure from the bulk substrate region, and removing the transfer device after mounting the separated substrate film-based semiconductor device structure on the carrier.

In some examples, the under-etch to partially remove the ion-induced damage layer comprises a plasma etch. In other examples, the under-etch comprises a wet etch.

In some examples, the semiconductor substrate comprises silicon carbide, gallium nitride, or diamond.

In some examples, the implant depth of the ion-induced damage layer is in the range of 0.4-1.0 μm below an upper surface of the semiconductor substrate.

In some examples, the method includes after mounting the separated substrate film-based semiconductor device structure on the carrier, dicing the semiconductor device structure to define a plurality of discrete devices.

In some examples, forming semiconductor devices on the substrate film region includes growing an epitaxial region over the substrate film region, and forming metal structures over the epitaxial region, and the plurality of vertical openings extend vertically through the epitaxial region and the substrate film region.

In some examples, the plurality of vertical openings extend at least partially through a vertical thickness of the ion-induced damage layer.

In some examples, the method includes after separating the substrate film-based semiconductor device structure from the bulk substrate region, using the separated bulk substrate region to form additional devices.

One aspect provides a method including forming semiconductor device components on a semiconductor substrate to define a semiconductor device structure; forming at least one vertical opening extending though a partial vertical thickness of the semiconductor substrate; performing an under-etch through the at least one vertical opening, wherein the under-etch forms a horizontally extending weakened layer within the semiconductor substrate; using the horizontally extending weakened layer to separate the semiconductor substrate into (a) a substrate film region above the horizontally extending weakened layer and (b) an underlying bulk substrate region below the horizontally extending weakened layer, the separated substrate film region carrying the semiconductor device components to collectively define a substrate film-based semiconductor device structure; and mounting the separated substrate film-based semiconductor device structure on a carrier.

In some examples, the method includes performing an ion beam implant in the semiconductor substrate to form an ion-induced damage layer at an implant depth in the semiconductor substrate, wherein a portion of the substrate above the ion-induced damage layer defines the substrate film region, and a portion of the substrate below the ion-induced damage layer defines the bulk substrate region. The at least one vertical opening extends at least partially through a vertical thickness of the ion-induced damage layer, and the under-etch removes a portion of the ion-induced damage layer.

In some examples, the method includes securing a transfer device to the top side of the semiconductor device structure prior to separating the semiconductor substrate, and removing the transfer device after mounting the separated substrate film-based semiconductor device structure on the carrier.

In some examples, the under-etch comprises a plasma etch. In other examples, the under-etch comprises a wet etch.

In some examples, the semiconductor substrate comprises silicon carbide, gallium nitride, or diamond.

In some examples, the method includes after mounting the separated substrate film-based semiconductor device structure on the carrier, dicing the semiconductor device structure to define a plurality of discrete devices.

In some examples, forming semiconductor devices on the semiconductor substrate includes growing an epitaxial region over the semiconductor substrate and forming metal structures over the epitaxial region, and the plurality of vertical openings extend vertically through the epitaxial region.

In some examples, the method includes after separating the substrate film region from the bulk substrate region, using the separated bulk substrate region to form additional devices.

### BRIEF DESCRIPTION OF THE DRAWINGS

Example aspects of the present disclosure are described below in conjunction with the figures, in which:

FIG. 1 is a flowchart showing an example method of forming semiconductor devices; and

FIGS. 2A-2I are a series of cross-sectional side views illustrating an example method for forming semiconductor devices.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

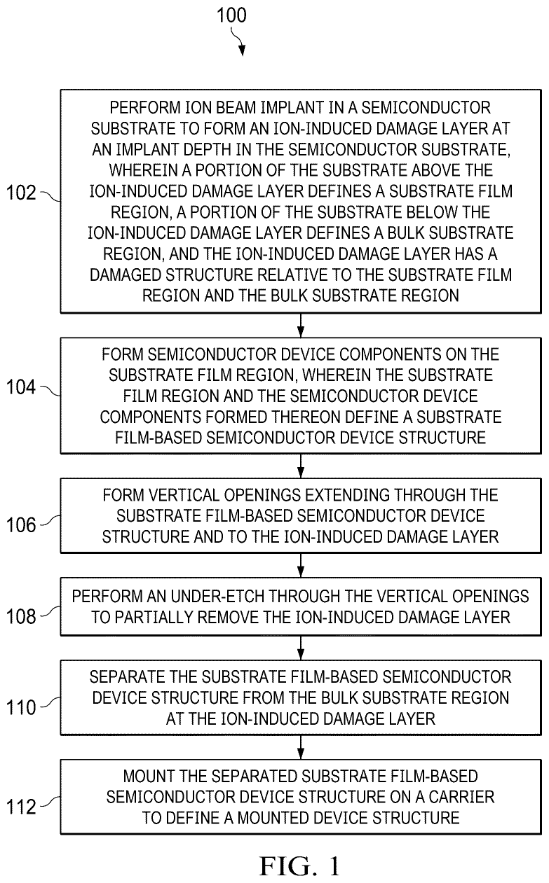

FIG. 1 is a flowchart 100 showing an example method of forming semiconductor devices. At 102, an ion beam implant (e.g., comprising H₂, helium, or other suitable ions) is performed in a semiconductor substrate to form an ion-induced damage layer at an implant depth in the semiconductor substrate, wherein a portion of the substrate above the ion-induced damage layer defines a substrate film region, a portion of the substrate below the ion-induced damage layer defines a bulk substrate region, and the ion-induced damage layer has a damaged structure relative to the substrate film region and the bulk substrate region.

In some examples, the semiconductor substrate may comprise silicon carbide (SIC), gallium nitride (GaN), or diamond. In some examples, the implant depth of the ion-induced damage layer is in the range of 0.35-1.0 μm below an upper surface of the semiconductor substrate.

At 104, semiconductor device components are formed on the substrate film region, wherein the substrate film region and the semiconductor device components formed thereon define a substrate film-based semiconductor device structure. Forming semiconductor device components on the substrate film region may include growing an epitaxial region over the substrate film region, and forming metal structures over the epitaxial region.

At 106, a plurality of vertical openings are formed, extending through the substrate film-based semiconductor device structure and to the ion-induced damage layer. In some examples, the vertical openings may be formed by a plasma etch or a mechanical cutting process. In some examples, the vertical openings comprise vertical grooves or channels extending in a lateral direction, wherein forming such vertical openings may be considered a partial dicing of the structure. As used herein, a vertical opening extending “to the ion-induced damage layer” refers to a vertical opening extending down to a top of the ion-induced damage layer, or extending down through a partial thickness of the ion-induced damage layer, or extending through a full thickness of the ion-induced damage layer, depending on the particular implementation.

At 108, an under-etch is performed through the vertical openings to partially remove the ion-induced damage layer. In some examples, the under-etch of the ion-induced damage layer comprises a plasma etch. In other examples, the under-etch comprises a wet etch. In some examples, the under-etch may be selective to the ion-induced damage layer (as opposed to the substrate film region and bulk substrate region) based on the weakened structure of the ion-induced damage layer, such that the remainder of the semiconductor substrate (including the substrate film region and bulk substrate region) remains fully or substantially intact.

At 110, the substrate film-based semiconductor device structure is separated from the bulk substrate region at the partially removed ion-induced damage layer. The separation of the substrate film-based semiconductor device structure from the bulk substrate region is facilitated by the ion-induced damage layer being partially removed and/or based on the weakened structure resulting from the ion beam implant. A thickness of the original semiconductor substrate is thereby reduced at least by a thickness of substrate film region.

At 112, the separated substrate film-based semiconductor device structure is mounted on a carrier to define a mounted device structure.

In some examples, a transfer device may be secured to the substrate film-based semiconductor device structure (e.g., to metal structures formed on an epitaxial region) prior to separating the substrate film-based semiconductor device structure from the bulk substrate region at 110, and the transfer device may be removed after mounting the separated substrate film-based semiconductor device structure on the carrier at 112.

In some examples, the die carrier may be diced, e.g., using a plasma etch or a mechanical cut through the vertical openings formed at 104 and/or at other locations, to form a plurality of discrete devices.

In some examples, the bulk substrate region separated from the substrate film-based semiconductor device structure at 110 may be reused in one or more further instances of the method 100 to form additional devices, e.g., wherein the thickness of the bulk substrate region is further reduced during each successive instance of the method 100.

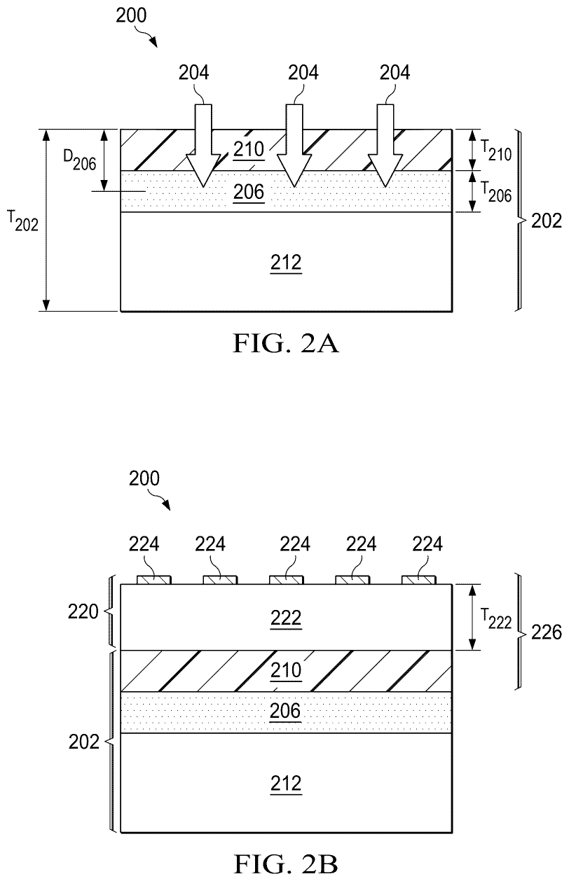

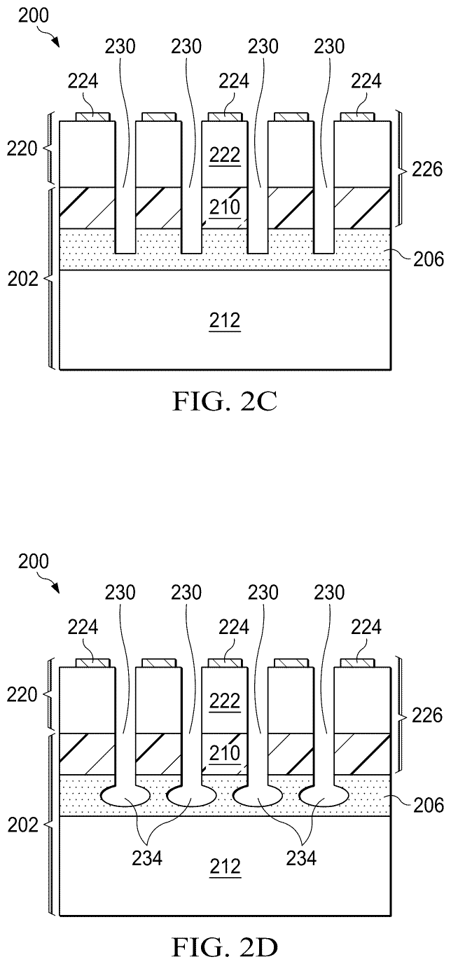

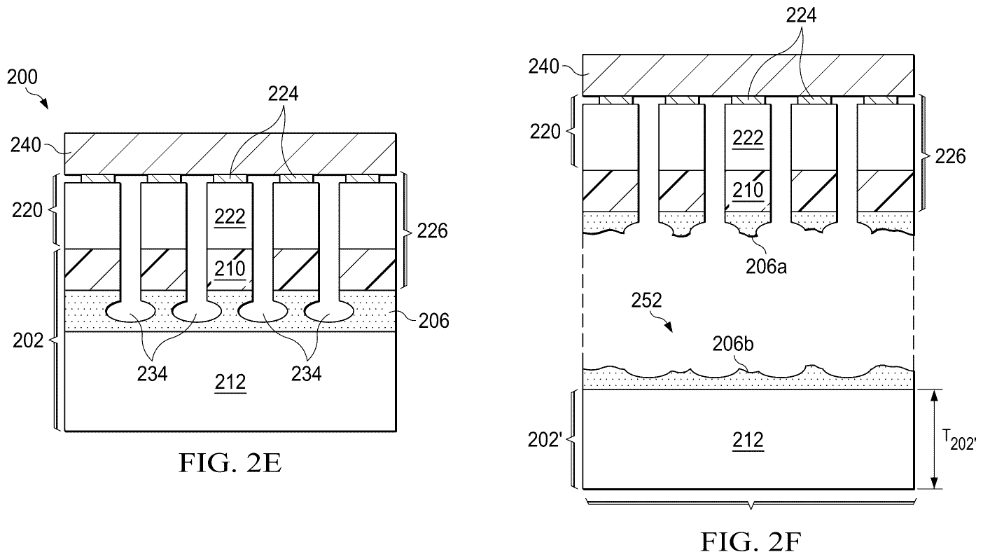

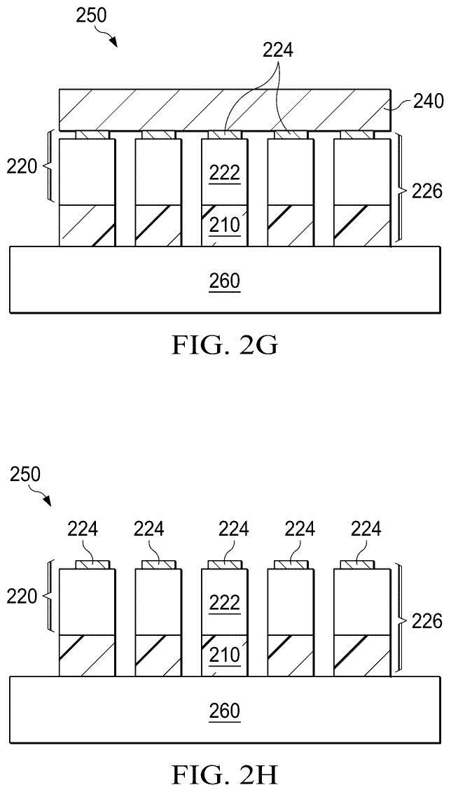

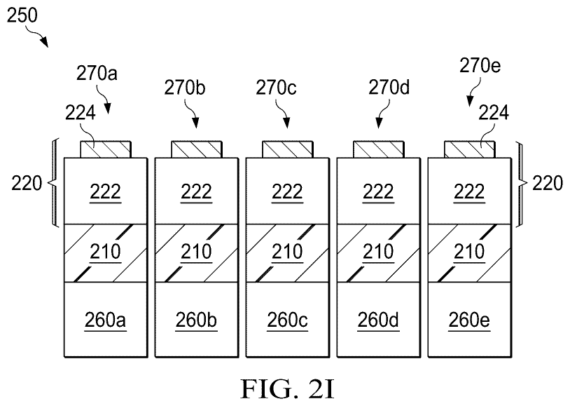

FIGS. 2A-2I are a series of cross-sectional side views illustrating an example method for forming semiconductor devices. The method shown in FIGS. 2A-2I may correspond with method 100 shown in FIG. 1 and discussed above, along with additional details.

As shown in FIG. 2A, a structure 200 may include a semiconductor substrate 200, e.g., comprising silicon carbide (SiC), gallium nitride (GaN), or diamond. In some examples, the semiconductor substrate 200 may have a thickness T₂₀₂ in the range of 100-500 μm, for example about 350 μm.

An ion beam implant, indicated at 204, is performed in the semiconductor substrate 202 to form an ion-induced damage layer 206 at an implant depth D₂₀₆ in the semiconductor substrate 202. In some examples, the ion beam implant may comprise an implant of H₂, helium, or other suitable ions, with an ion energy in the range of 55-180 keV. The type of implant ions used may depend on the material of the semiconductor substrate 202. For example, He ions may be used for a semiconductor substrate 202 comprising SiC or diamond.

A portion of the semiconductor substrate 202 above the ion-induced damage layer 206 defines a substrate film region 210 (i.e., a thin upper layer of the semiconductor substrate 202), and a portion of the semiconductor substrate 202 below the ion-induced damage layer 206 defines a bulk substrate region 212. As discussed below (e.g., with reference to FIG. 2D), the ion-induced damage layer 206 may be used to facilitate a separation of the upper substrate film region 210 from the bulk substrate region 212.

The ion-induced damage layer 106 has a damaged structure relative to the substrate film region 210 and the bulk substrate region 212. In some examples, implant depth D₂₀₆ of the ion-induced damage layer 106, e.g., measured from an upper surface of the semiconductor substrate 202 to a vertical midpoint of the ion-induced damage layer 206, is in the range of 0.35 μm to 1.0 μm (350-1000 nm). The implant depth D₂₀₆ may be controlled by selecting the implant energy level and/or other parameters of the ion beam implant 204. For example, an ion implant performed with an ion energy of 65 keV may provide an implant depth D₂₀₆ in the range of 0.35-0.45 μm (350-450 nm), whereas an ion implant performed with an ion energy of 140 keV may provide an implant depth D₂₀₆ in the range of 0.75-0.85 μm (750-850 nm).

In some examples, the ion-induced damage layer 106 may have a thickness T₂₀₆ in the range of 10-90 nm for example in the range of 20-50 nm.

In view of the example ranges of the implant depth D₂₀₆ and thickness T₂₀₆ of the ion-induced damage layer 106, the substrate film region 210 above the ion-induced damage layer 106 may have a thickness T₂₀₆ in the range of 0.345-0.995 μm (345-995 nm).

As shown in FIG. 2B, semiconductor device components 220 may be formed on the substrate film region 210. Semiconductor device components 220 may include, for example, one or more structures of at least one bipolar power device (e.g., at least one transistor, thyristor, or pin diode, without limitation) and/or at least one unipolar device (e.g., at least one MOSFET or Junction Barrier Schottky (JBS) device, without limitation). Some semiconductor device components 220 may comprise metal structures, e.g., formed in one or more metal layers.

In some examples, e.g., as shown in FIG. 2B, forming semiconductor device components 220 may include (a) growing an epitaxial region 222 (e.g., including or defining structures of respective semiconductor device components 220) over the substrate film region 210 and (b) forming metal structures 224 over the epitaxial region 222. In some examples, the epitaxial region 222 may have a thickness T₂₂₂ in the range of 3-50 μm.

As shown in FIG. 2B, the substrate film region 210 and the semiconductor device components 220 formed thereon collectively define a substrate film-based semiconductor device structure 226.

As shown in FIG. 2C, a plurality of vertical openings 230 are formed, extending through the substrate film-based semiconductor device structure 226 (e.g., through metal structures 224, epitaxial region 222, and substrate film region 210) and to the ion-induced damage layer 206. In some examples, the vertical openings 230 may be formed using a plasma etch or a mechanical cutting process.

In some examples, respective vertical openings 230 comprise vertical grooves or channels extending in a lateral direction (i.e., into the page in the view shown in FIG. 2C), wherein forming such vertical openings 230 may be considered a partial dicing of the structure 200. In some examples, respective vertical openings 230 may extend down to a top of the ion-induced damage layer 206, or may extend down through a partial vertical thickness of the ion-induced damage layer 206 (e.g., as shown in FIG. 2C), or may extend through a full thickness of the ion-induced damage layer 206, depending on the particular implementation.

As shown in FIG. 2D, an under-etch is performed through the vertical openings 230 to partially remove the ion-induced damage layer 206, for example to form voids 234 in the ion-induced damage layer 206. In some examples, the under-etch of the ion-induced damage layer 206 may involve a plasma etch process or a wet etch process. As shown, the voids 234 formed by the under-etch may extend laterally within the ion-induced damage layer 206, for example extending laterally under intact regions of the substrate film region 210. In some examples, the voids 234 may comprise at least 25%, at least 50%, or at least 75% of the (pre-under-etch) volume of the ion-induced damage layer 206 across a respective region of the ion-induced damage layer 206 (e.g., a region laterally spanning two or more vertical openings 230).

As shown in FIG. 2E, a transfer device 240 (e.g., a transfer stamp) may be secured to an upper side of the substrate film-based semiconductor device structure 226 (e.g., to an upper side of metal structures 224), for example using a tape or other adhesive, or using vacuum/suction force in the case of a transfer device 240 comprising a vacuum chuck.

As shown in FIG. 2F, the substrate film-based semiconductor device structure 226 may be separated from the bulk substrate region 212 at the ion-induced damage layer 206. For example, the transfer device 240 (e.g., transfer stamp) may be used to lift the substrate film-based semiconductor device structure 226 off the bulk substrate region 212, which bulk substrate region 212 may remain secured to a mounting apparatus. The separation of the substrate film-based semiconductor device structure 226 from the bulk substrate region 212 (at the ion-induced damage layer 206) may be facilitated by the ion-induced damage layer 206 being partially removed by the under-etch discussed above and/or based on the weakened structure resulting from the ion beam implant discussed above.

As shown, a first partial portion 206a of the ion-induced damage layer 206 may remain adhered to the upper substrate film region 210, while a second partial portion 206b of the ion-induced damage layer 206 may remain adhered to the bulk substrate region 212.

In some examples, the bulk substrate region 212 may define a reduced-thickness semiconductor substrate 202′ which may be reused to form additional devices by repeating the processes shown in FIGS. 2A-2I with the reduced-thickness semiconductor substrate 202′. In some examples, the second partial portion 206b of the ion-induced damage layer 206 may be cleaned or otherwise removed before reusing the bulk substrate region 212 (reduced-thickness semiconductor substrate 202′). In this manner, a semiconductor substrate (e.g., an SiC, GaN, or diamond wafer substrate) may be reused multiple times to produce multiple groups of devices, wherein a thin layer of the semiconductor substrate is removed during each iteration. The thin layer of the semiconductor substrate removed during each iteration may comprise at least the upper substrate film region 210 and the ion-induced damage layer 206.

As shown in FIG. 2G, the transfer device 240 may carry and mount the separated substrate film-based semiconductor device structure 226 on a carrier 260 (e.g., a die carrier), to define a mounted device structure 250. The substrate film-based semiconductor device structure 226 may be bonded to the carrier 260, e.g., using a highly thermally and electrically conductive adhesive. In some examples, the carrier 260 may comprise a material having high thermal and electrical conductivity, for example, polycrystalline SiC, copper, or other suitable material. In other examples, the carrier 260 may comprise a dielectric substrate.

In some examples, the first partial portion 206a on the bottom surface of the ion-induced damage layer 206 may be maintained (i.e., not removed), as the material of the ion-induced damage layer 206 may improve a thermal and/or electrical connection between the upper substrate film region 210 and the carrier 260. In other examples, the first partial portion 206a may be cleaned or otherwise removed from the bottom surface of the ion-induced damage layer 206 before mounting the substrate film-based semiconductor device structure 226 on the carrier 260.

As shown in FIG. 2H, the transfer device 240 may be removed from the mounted device structure 250, e.g., by detaching the transfer device 240 from the metal structures 224.

As shown in FIG. 2I, a dicing or cutting process may be performed, e.g., using a plasma etch or a mechanical cut, to dice (cut) the mounted device structure 250 into a plurality of discrete devices 270a-270e, each mounted on a respective die carrier structure 260a-260e.

Although example embodiments have been described above, other variations and embodiments may be made from this disclosure without departing from the spirit and scope of these embodiments.

1. A method, comprising:
performing an ion beam implant in a semiconductor substrate to form an ion-induced damage layer at an implant depth in the semiconductor substrate, wherein a portion of the substrate above the ion-induced damage layer defines a substrate film region, and a portion of the substrate below the ion-induced damage layer defines a bulk substrate region, and the ion-induced damage layer has a damaged structure relative to the substrate film region and the bulk substrate region; and
forming semiconductor device components on the substrate film region, wherein the substrate film region and the semiconductor device components formed thereon define a substrate film-based semiconductor device structure;
forming a plurality of vertical openings through the substrate film-based semiconductor device structure and extending to the ion-induced damage layer;
performing an under-etch through the vertical openings to partially remove the ion-induced damage layer;
separating the substrate film-based semiconductor device structure from the bulk substrate region, wherein the separation occurs at the partially removed ion-induced damage layer; and
mounting the separated substrate film-based semiconductor device structure on a carrier.

2. The method of claim 1, comprising:
securing a transfer device to the top side of the semiconductor device structure prior to separating the substrate film-based semiconductor device structure from the bulk substrate region; and
removing the transfer device after mounting the separated substrate film-based semiconductor device structure on the carrier.

3. The method of claim 1, wherein the under-etch to partially remove the ion-induced damage layer comprises a plasma etch.

4. The method of claim 1, wherein the under-etch to partially remove the ion-induced damage layer comprises a wet etch.

5. The method of claim 1, wherein the semiconductor substrate comprises silicon carbide, gallium nitride, or diamond.

6. The method of claim 1, wherein the implant depth of the ion-induced damage layer is in the range of 0.4-1.0 μm below an upper surface of the semiconductor substrate.

7. The method of claim 1, comprising after mounting the separated substrate film-based semiconductor device structure on the carrier, dicing the semiconductor device structure to define a plurality of discrete devices.

8. The method of claim 1, wherein:
forming semiconductor devices on the substrate film region comprises:
growing an epitaxial region over the substrate film region; and
forming metal structures over the epitaxial region; and
the plurality of vertical openings extend vertically through the epitaxial region and the substrate film region.

9. The method of claim 1, wherein the plurality of vertical openings extend at least partially through a vertical thickness of the ion-induced damage layer.

10. The method of claim 1, comprising after separating the substrate film-based semiconductor device structure from the bulk substrate region, using the separated bulk substrate region to form additional devices.

11. A method, comprising:
forming semiconductor device components on a semiconductor substrate to define a semiconductor device structure;
forming at least one vertical opening extending though a partial vertical thickness of the semiconductor substrate;
performing an under-etch through the at least one vertical opening, wherein the under-etch forms a horizontally extending weakened layer within the semiconductor substrate;
using the horizontally extending weakened layer to separate the semiconductor substrate into (a) a substrate film region above the horizontally extending weakened layer and (b) an underlying bulk substrate region below the horizontally extending weakened layer, the separated substrate film region carrying the semiconductor device components to collectively define a substrate film-based semiconductor device structure; and
mounting the separated substrate film-based semiconductor device structure on a carrier.

12. The method of claim 11, comprising:
performing an ion beam implant in the semiconductor substrate to form an ion-induced damage layer at an implant depth in the semiconductor substrate, wherein a portion of the substrate above the ion-induced damage layer defines the substrate film region, and a portion of the substrate below the ion-induced damage layer defines the bulk substrate region;
wherein the at least one vertical opening extends at least partially through a vertical thickness of the ion-induced damage layer; and
the under-etch removes a portion of the ion-induced damage layer.

13. The method of claim 11, comprising:
securing a transfer device to the top side of the semiconductor device structure prior to separating the semiconductor substrate; and
removing the transfer device after mounting the separated substrate film-based semiconductor device structure on the carrier.

14. The method of claim 11, wherein the under-etch comprises a plasma etch.

15. The method of claim 11, wherein the under-etch comprises a wet etch.

16. The method of claim 11, wherein the semiconductor substrate comprises silicon carbide, gallium nitride, or diamond.

17. The method of claim 11, comprising after mounting the separated substrate film-based semiconductor device structure on the carrier, dicing the semiconductor device structure to define a plurality of discrete devices.

18. The method of claim 11, wherein:
forming semiconductor devices on the semiconductor substrate comprises:
growing an epitaxial region over the semiconductor substrate; and
forming metal structures over the epitaxial region; and
the plurality of vertical openings extend vertically through the epitaxial region.

19. The method of claim 11, comprising after separating the substrate film region from the bulk substrate region, using the separated bulk substrate region to form additional devices.
